(19) United States
(12) Patent Application Publication
(10) Pub. No.: US 2025/0275209 A1
(43) Pub. Date: Aug. 28, 2025

(54) DEUTERIUM-TREATED FERROELECTRIC DEVICES AND METHODS FOR FABRICATING THE SAME

(71) Applicant: TetraMem Inc., Fremont, CA (US)

(72) Inventors: Minxian Zhang, Amherst, MA (US); Ning Ge, Danville, CA (US)

(73) Assignee: TetraMem Inc., Fremont, CA (US)

(21) Appl. No.: 18/590,746

(22) Filed: Feb. 28, 2024

(51) Int. Cl. H01L 21/28; H01L 21/30; H01L 23/48; H01L 29/51; H10B 51/30; H10B 53/30

(52) U.S. Cl. CPC H10D 64/033; H01L 21/3003; H01L 23/481; H10B 51/30; H10B 53/30; H10D 64/689

(57) ABSTRACT

In accordance with some embodiments of the present disclosure, a ferroelectric device is provided. The memory device may include. a first electrode, a ferroelectric layer fabricated on the first electrode, and a second electrode fabricated on the ferroelectric layer. The ferroelectric layer comprises a ferroelectric material and deuterium. The ferroelectric layer may include at least one ferroelectric material, such as hafnium oxide (HfO₂), zirconium oxide (ZrO₂), zirconium-doped hafnium oxide (Hf₁₋ₓZrₓO₂), scandium-doped aluminum nitride (Al₁₋ₓScₓN), titanates (BaTiO₃), niobates (LiNbO₃), tantalates (NaTaO₃), etc. Fabricating the memory device may involve fabricating a ferroelectric device stack containing the first electrode, the ferroelectric layer, and the second electrode; and performing deuterium treatment on the ferroelectric device stack.

### TECHNICAL FIELD

The implementations of the disclosure generally relate to memory and computing devices and, more specifically, to deuterium-treated ferroelectric devices and methods for fabricating the same.

### BACKGROUND

Ferroelectric materials may refer to materials that exhibit a spontaneous electric polarization that can be reversed in direction by the application of a suitable electric field, such as hafnium oxide (HfO₂), zirconium oxide (ZrO₂), zirconium-doped hafnium oxide (Hf₁₋ₓZrₓO₂), scandium-doped aluminum nitride (Al₁₋ₓScₓN), titanates (BaTiO₃), niobates (LiNbO₃), tantalates (NaTaO₃), etc. The ferroelectric materials may remain polarized even when the electric field is removed. As such, the ferroelectric materials may store data when power is disconnected from it. This makes the ferroelectric materials promising candidates for implementing non-volatile memory that remains stored data even when its external power supply is disconnected.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, an apparatus including a ferroelectric device is provided. The apparatus comprises a first electrode, a ferroelectric layer fabricated on the first electrode, and a second electrode fabricated on the ferroelectric layer. The ferroelectric layer includes a ferroelectric material and deuterium.

In some embodiments, the ferroelectric material includes a deuterium-treated metal oxide, and wherein the metal oxide includes at least one of hafnium oxide (HfO₂), zirconium oxide (ZrO₂), zirconium-doped hafnium oxide (Hf₁₋ₓZrₓO2 with x ranging from 0 to 1), scandium-doped aluminum nitride (Al₁₋ₓScₓN with x>0.3), titanates (BaTiO₃), niobates (LiNbO₃), or tantalates (NaTaO₃).

In some embodiments, the ferroelectric material is interstitially doped with at least one interstitial dopant, wherein the at least one interstitial dopant includes at least one of H, N, C, B, or F.

In some embodiments, the first electrode includes at least one of tungsten, ruthenium, molybdenum, titanium nitride, tantalum nitride, tungsten nitride, platinum, palladium, or iridium.

In some embodiments, the second electrode includes at least one of tungsten, ruthenium, molybdenum, titanium nitride, tantalum nitride, tungsten nitride, platinum, palladium, or iridium.

In some embodiments, the apparatus further includes a first connection pad, wherein the first electrode is fabricated on the first connection pad, and wherein the first connection pad includes a conductive material.

In some embodiments, the apparatus further includes a substrate, wherein the first connection pad is fabricated on the substrate.

In some embodiments, the apparatus further includes a second connection pad, wherein the second connection pad is fabricated on the second electrode.

In some embodiments, the second connection pad includes a metallic pad and a metallic via.

According to one or more aspects of the present disclosure, a method for fabricating a ferroelectric device includes: fabricating a ferroelectric device stack, wherein the ferroelectric device stack includes a first electrode, a second electrode, and a ferroelectric layer between the first electrode and the second electrode, wherein the ferroelectric layer includes a ferroelectric material; and performing deuterium treatment on the ferroelectric device stack to obtain a deuterium-treated ferroelectric device stack, wherein the ferroelectric layer in the deuterium-treated ferroelectric device stack includes deuterium.

In some embodiments, the method further includes fabricating a connection pad on the deuterium-treated ferroelectric device stack.

In some embodiments, fabricating the connection pad includes fabricating at least one of a metallic pad or a metallic via.

In some embodiments, the ferroelectric material includes a metal oxide, and wherein the metal oxide includes at least one of hafnium oxide (HfO₂), zirconium oxide (ZrO₂), zirconium-doped hafnium oxide (Hf₁₋ₓZrₓO2 with x ranging from 0 to 1), scandium-doped aluminum nitride (Al₁₋ₓScₓN with x>0.3), titanates (BaTiO₃), niobates (LiNbO₃), or tantalates (NaTaO₃).

In some embodiments, the first electrode includes at least one of tungsten, ruthenium, molybdenum, titanium nitride, tantalum nitride, tungsten nitride, platinum, palladium, or iridium.

In some embodiments, the second electrode includes at least one of tungsten, ruthenium, molybdenum, titanium nitride, tantalum nitride, tungsten nitride, platinum, palladium, or iridium.

In some embodiments, performing the deuterium treatment on the ferroelectric device stack includes exposing the ferroelectric device stack in an ambient atmosphere including nitrogen gas (N₂) and deuterium gas (D₂).

In some embodiments, fabricating the ferroelectric device stack includes fabricating, on a connection pad, a first electrode layer, fabricating one or more ferroelectric films on the first electrode layer, and fabricating a second electrode on the ferroelectric layer.

In some embodiments, fabricating the ferroelectric device stack further includes selectively removing one or more portions of the first electrode layer, the ferroelectric films, and the second electrode layer.

In some embodiments, the ferroelectric device stack is fabricated on a connection pad, wherein the connection pad includes a conductive material.

In some embodiments, the method further includes applying heat treatment to the deuterium-treated ferroelectric device stack.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 illustrates a cross-sectional view of an example ferroelectric device in accordance with some embodiments of the present disclosure.

FIGS. 2A, 2B, 2C, 2D, and 2E illustrate structures related to a process for fabricating a ferroelectric device in accordance with some embodiments of the present disclosure.

FIG. 3A is a flow chart illustrating an example process for fabricating a ferroelectric device in accordance with some embodiments of the present disclosure.

FIG. 3B is a flow chart illustrating an example process for fabricating a ferroelectric device stack in accordance with some embodiments of the present disclosure.

FIG. 4 is a schematic diagram illustrating an example memory cell in accordance with some embodiments of the present disclosure.

FIG. 5A is a flow chart illustrating an example process for fabricating an interconnect structure in accordance with some embodiments of the present disclosure.

FIGS. 5B-5G illustrate cross-sectional views of structures for fabricating an interconnect structure in accordance with some embodiments of the present disclosure.

### DETAILED DESCRIPTION

Aspects of the present disclosure provide ferroelectric devices and methods for making the same. The ferroelectric devices may be a capacitor (e.g., ferroelectric capacitor (FeCAP)), a transistor (e.g., ferroelectric field-effect transistor (FeFET)), a ferroelectric tunneling junction (FTJ), a ferroelectric random-access memory (FeRAM), etc.

A ferroelectric material may be polarized in response to the application of an external electric field and may remain polarized even when the external electric field is removed. The reversible spontaneous polarization arises from non-centrosymmetric arrangements of ions in the ferroelectric material that produces a permanent electric dipole moment. Adjacent dipoles tend to orient themselves in the same direction to form a region referred to as a ferroelectric domain.

A material may have multiple polymorphs of varying ferroelectric properties. For example, HfO₂ may exhibit a monoclinic phase (m-phase) between room temperature and 1670° C. at equilibrium conditions. As the temperature increases, HfO₂ may undergo a phase transition from monoclinic (m-phase) to tetragonal (t-phase) and then to cubic (c-phase). HfO₂ does not exhibit ferroelectricity in the m-phase, the t-phase, or the c-phase. HfO₂ may exhibit ferroelectricity in a polar orthorhombic phase (o-phase). Although the m-HfO₂ phase is the most stable phase around ambient temperature thermodynamically, the o-HfO₂ phase shows distinctive properties due to its intrinsic non-centrosymmetric polar and ferroelectric behavior. Ferroelectricity in materials relates to the permanent electrical polarization of a crystalline dielectric under an electric field. Ferroelectric materials exhibit bi-state polarization behaviors, enabling them to store binary information of “0” and “1” in a non-volatile manner, making them suitable for memory devices.

Under extremely high pressures of 1 gigapascal (approximately 10,000 atmospheres), orthorhombic phases of HfO₂ materials exist, designated as Orthorhombic-I (oI-phase) and Orthorhombic-II (oII-phase). The ferroelectric phase required for certain applications is Orthorhombic-III (oIII-phase), which is characterized by the Miller index Pca21. This oIII-phase does not appear in the equilibrium phase diagram and may need to be synthesized through a process that is either favored or controlled by the kinetics of the reaction. Due to the kinetic favorability of the oIII-phase and the thermodynamically preferred m-phase, both the ferroelectric oIII-phase and the non-ferroelectric m-phase may co-exist in ferroelectric devices. This may occur when insufficient oIII formation is in the device and can result in inadequate ferroelectric signal strength. To amplify signal intensity, one approach is to increase the size of the device film, thereby enhancing the amount of oIII-phase present. However, merely enlarging the lateral size of the device will not address this issue. A thicker film may lead to larger polycrystalline grain size and more variability at the grain boundaries, potentially increasing the device's leakage current. Additionally, smaller grain size corresponds to reduced ferroelectric domain size, since a single grain may contain multiple ferroelectric domain sizes. Moreover, a higher number of domains could provide multiple domain wall orientations, such as 0 degrees (parallel), 180 degrees (anti-parallel), and other orientations, which may be beneficial for multilevel FeRAM applications.

The present disclosure provides ferroelectric devices and methods for fabricating the same. In some embodiments, a ferroelectric device may include a ferroelectric device stack containing one or more ferroelectric films. The ferroelectric device stack may further include a first electrode and a second electrode. The ferroelectric films are fabricated between the first electrode and the second electrode. Each of the ferroelectric films may include a ferroelectric material. The ferroelectric material may include a metal oxide (e.g., HfO₂, ZrO₂, Hf₁₋ₓZrₓO₂ with x ranging from 0 to 1, Al₁₋ₓScₓN with x>0.3, BaTiO₃, LiNbO₃, NaTaO₃, etc.).

Deuterium (D or D₂) is a stable isotope of hydrogen and is not radioactive. Each deuterium isotope has one proton, one neutron, and one electron. Deuterium treatment may be performed on the ferroelectric device stack to create a small number of oxygen vacancies, which may form a deuterium-oxygen vacancy pair known as D-Vo. The deuterium treatment may enhance the formation of the ferroelectric oIII phase and may inhibit the formation of the non-ferroelectric m-phase. The permeability of deuterium through the second electrode, such as TaN and TiN, may enable this deuterium treatment to be carried out after the ferroelectric device stack has been fully fabricated (e.g., after the deposition and patterning of the entire device stack). Additionally, the deuterium treatment, which occurs in a slightly reducing atmosphere, can generate a controlled amount of oxygen vacancies. These vacancies may promote the nucleation of the oIII phase, thus bolstering the formation of this phase and concurrently preventing the emergence of the m-phase, ultimately achieving a high ferroelectric intensity.

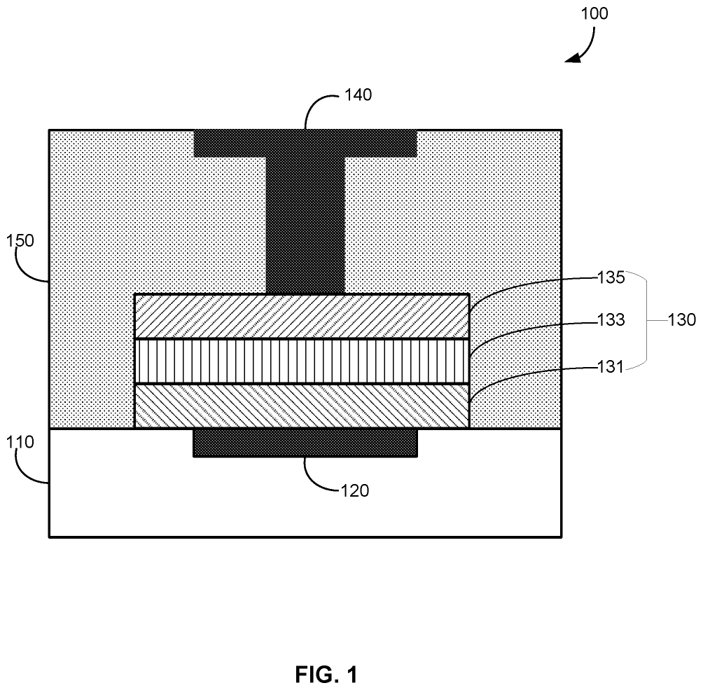

FIG. 1 illustrates a cross-sectional view of an example ferroelectric device 100 in accordance with some embodiments of the present disclosure.

As shown, ferroelectric device 100 may include a substrate 110, a first connection pad 120, a ferroelectric device stack 130, and a second connection pad 140. Second connection pad 140 may include a connection via (e.g., a metallic via) and a connection pad (e.g., a metallic pad) in some embodiments. Ferroelectric device 100 may further include a dielectric layer 150 surrounding second connection pad 140 and ferroelectric device stack 130. Ferroelectric device 100 may be a non-volatile memory device that can retain stored data even when it is not powered.

Substrate 110 may include any suitable materials for providing a base for the fabrication of the memory device, such as silicon, sapphire, silicon carbide, etc. In some embodiments, substrate 110 may include a driving circuit including one or more electrical circuits (e.g., an array of electrical circuits) that may be individually controllable. In some embodiments, the driving circuit may include one or more complementary metal-oxide-semiconductor (CMOS) drivers.

First connection pad 120 may be fabricated on substrate 110. In one implementation, the top surface of first connection pad 120 is elevated above the top surface of substrate 110. First connection pad 120 may include any suitable conductive material for providing ohmic contact for the device fabricated on first connection pad 120, such as metals, metal nitrides, alloys, etc. In some embodiments, substrate 110 may be a CMOS substrate, and first connection pad 120 may include an interconnect of the CMOS substrate (e.g., a metallic pad, metallic via, etc.).

Ferroelectric device stack 130 may include a first electrode 131, a ferroelectric layer 133, and a second electrode 135. First electrode 131 may include any suitable electrically conductive material. As an example, first electrode 131 may include metals such as tungsten (W), ruthenium (Ru), molybdenum (Mo), platinum (Pt), palladium (Pd), iridium (Ir), etc. As another example, first electrode 131 may include nitrides, such as titanium nitride (TiN), tantalum nitride (TaN), tungsten nitride (WN), etc.

Ferroelectric layer 133 may include one or more ferroelectric films conformally fabricated on first electrode 131. Each of the ferroelectric films may include a ferroelectric material undergone deuterium treatment (also referred to as a deuterium-treated ferroelectric material). The ferroelectric material may include a metal oxide, such as hafnium oxide (HfO₂), zirconium oxide (ZrO₂), zirconium-doped hafnium oxide (Hf₁₋ₓZrₓO₂) with x ranging from 0 to 1, scandium-doped aluminum nitride (Al₁₋ₓScₓN) with x>0.3, titanates (BaTiO₃), niobates (LiNbO₃), tantalates (NaTaO₃), etc. In some embodiments, the metal oxide may be doped with one or more substitutional and/or interstitial dopants that may occupy the vacant space between the atoms of the ferroelectric material. The interstitial dopant may include an element having an atomic radius that is not greater than an atomic radius of a metal element of the metal oxide. The metal oxide may include at least one of hafnium or zirconium. The interstitial dopant may include a nonmetal element, such as H, N, C, B, F, etc. The interstitial dopants may be introduced in the ferroelectric film utilizing an ion implantation method, a co-sputtering method, an alternating sputtering method, a thermal diffusion method, a chemical absorption method, and/or any other suitable technique. In some embodiments, the dopant concentration of the interstitial dopants(s) may be about or less than 10%.

Second electrode 135 may include any suitable electrically conductive material conformally fabricated on ferroelectric layer 133. For example, second electrode 135 may include metals, such as W, Ru, Mo, Pt, Pd, Ir, etc., and/or nitrides (e.g., TiN, TaN, WN, etc.). Second electrode 135 and first electrode 131 may or may not include the same materials.

In some embodiments, both first electrode 131 and second electrode 135 are non-reactive electrodes and do not include reactive metals (e.g., Ti, Ta, Hf, etc.).

Second connection pad 140 may contain any suitable conductive material for providing ohmic contact for ferroelectric device stack 130, such as metals, metal nitrides, alloys, etc. In some embodiments, second connection pad 140 may include one or more interconnects (e.g., a metallic pad, metallic via, etc.). As shown, second connection pad 140 may be fabricated in dielectric layer 150. Dielectric layer 150 may include one or more suitable dielectric materials (e.g., silicon dioxide, silicon nitride, etc.) and may be fabricated on substrate 110. Dielectric layer 150 may cover ferroelectric device stack 130.

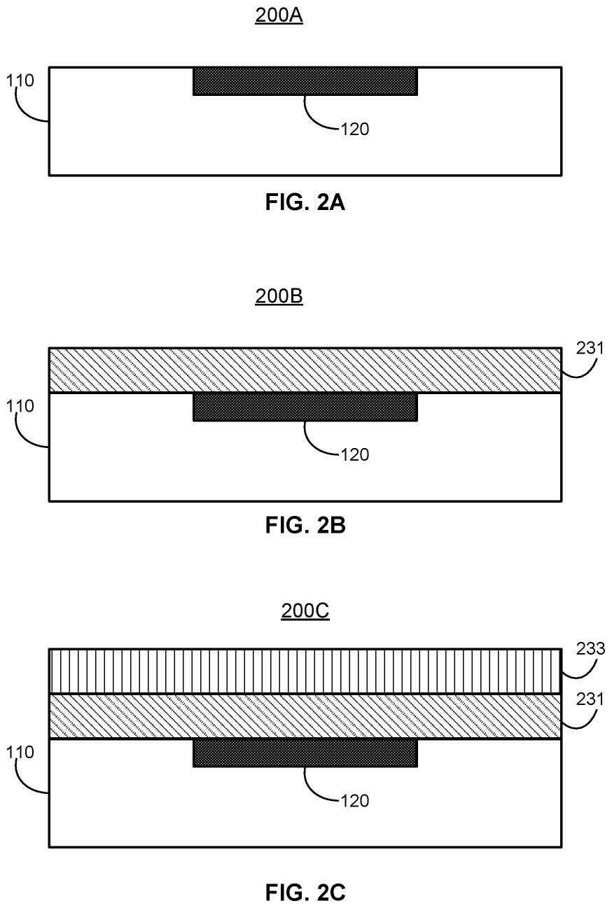

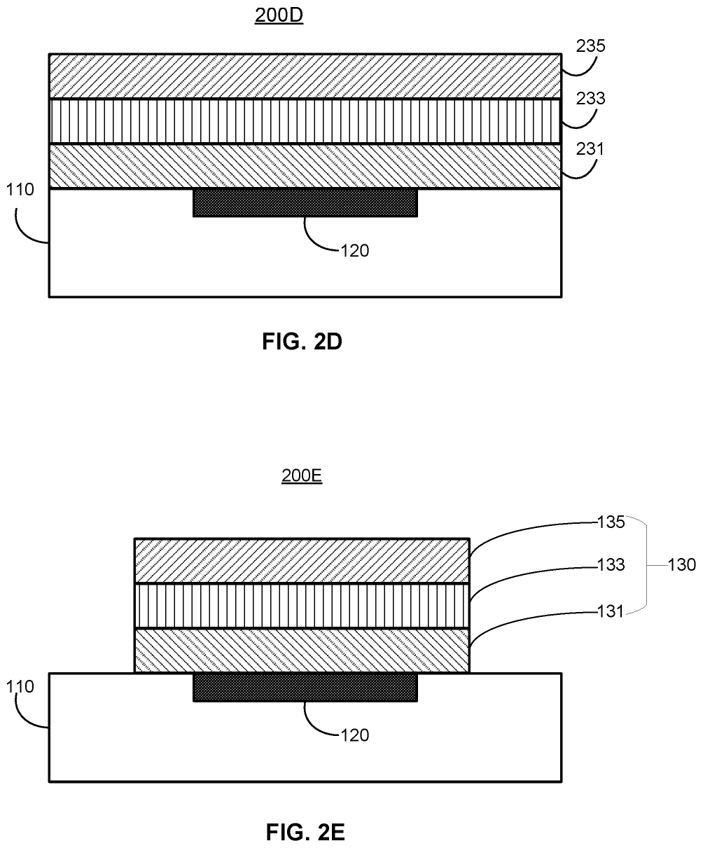

FIGS. 2A, 2B, 2C, 2D, and 2E illustrate structures 200A, 200B, 200C, 200D, and 200E related to a process for fabricating a ferroelectric device in accordance with some embodiments of the present disclosure.

As shown in FIG. 2A, a substrate 110 with a first connection pad 120 may be provided. First connection pad 120 may include any suitable conductive material, such as metals (e.g., tungsten (W), aluminum (Al), or copper (Cu)). In some embodiments, first connection pad 120 may be an interconnect of a CMOS substrate (e.g., a metallic pad, a metallic via, etc.).

As shown in FIG. 2B, a first electrode layer 231 may be fabricated on substrate 110 and first connection pad 120. First electrode layer 231 may include one or more layers of suitable electrically conductive materials (e.g., W, Ru, Mo, Pt, Pd, Ir, TiN, TaN, WN, etc.) deposited on substrate 110 and first connection pad 120. At least a portion of first electrode layer 231 directly contacts first connection pad 120. In some embodiments, an adhesion layer, such as a layer of Titanium (Ti) or a layer of Tantalum (Ta) may be applied between the first electrode and the first connection pad and between the first electrode and the substrate.

As shown in FIG. 2C, one or more ferroelectric films 233 may be fabricated on first electrode layer 231. Each of the ferroelectric films may include a ferroelectric material. The ferroelectric material may include a metal oxide (e.g., HfO₂, ZrO₂, Hf₁₋ₓZrₓO₂ with x ranging from 0 to 1, Al₁₋ₓScₓN with x>0.3, BaTiO₃, LiNbO₃, NaTaO₃, etc.). In some embodiments, the metal oxide may be doped with one or more substitutional and/or interstitial dopants that may occupy the vacant space between the atoms of the ferroelectric material. The interstitial dopant may include a nonmetal element, such as H, N, C, B, F, etc.

As shown in FIG. 2D, a second electrode layer 235 may be fabricated on ferroelectric films 233. Second electrode layer 235 may include one or more layers of one or more electrically conductive materials (e.g., W, Ru, Mo, Pt, Pd, Ir, TiN, TaN, WN, etc.).

As shown in FIG. 2E, one or more portions of first electrode layer 231, ferroelectric film(s) 233, and second electrode layer 235 may be selectively removed to fabricate a ferroelectric device stack 130. In particular, first electrode layer 231, ferroelectric film(s) 233, and second electrode layer 235 may be patterned and etched to fabricate first electrode 131, ferroelectric layer 133, and second electrode 135, respectively. While one ferroelectric device stack 130 is shown in FIG. 2E, this is merely illustrative. The patterning and etching of first electrode layer 231, ferroelectric film(s) 233, and second electrode layer 235 may fabricate a plurality of ferroelectric device stacks. Each of the ferroelectric devices may include a ferroelectric device stack 130.

Deuterium treatment may be performed on ferroelectric device stack 130. For example, ferroelectric device stack 130 and structure 200E may be exposed to a deuterium-containing atmosphere (e.g., an ambient atmosphere containing nitrogen gas (N₂) and deuterium gas (D₂), with a N₂ to D₂ ratio of 96:4) at elevated temperatures (e.g., 350° C.-500° C.), enabling deuterium to diffuse into ferroelectric layer 133. The deuterium treatment may reduce defects at the interface between first electrode 131 and ferroelectric layer 133 and/or the defects at the interface between ferroelectric layer 133 and second electrode 135. The deuterium treatment may further create a controlled amount of oxygen vacancies in the ferroelectric layer 133. In some embodiments, the deuterium treatment may last between about 15 minutes to about 60 minutes. The deuterium-treated ferroelectric device stacks and the deuterium-treated ferroelectric layer may thus contain deuterium, which can be detected by measurements such as high-resolution mass spectrometry, etc.

Referring back to FIG. 1, second connection pad 140 may be fabricated on second electrode 135 after the deuterium treatment. Second connection pad 140 may include a metallic via, a metallic pad, etc. fabricated within dielectric layer 150. Dielectric layer 150 is fabricated on substrate 110 and envelops the surface of ferroelectric device stack 130 and first connection pad 120.

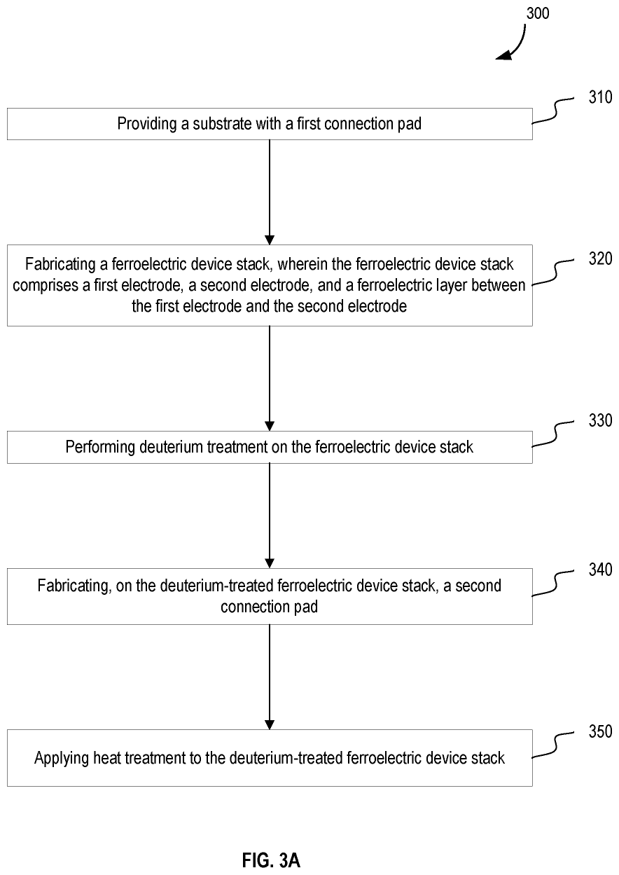

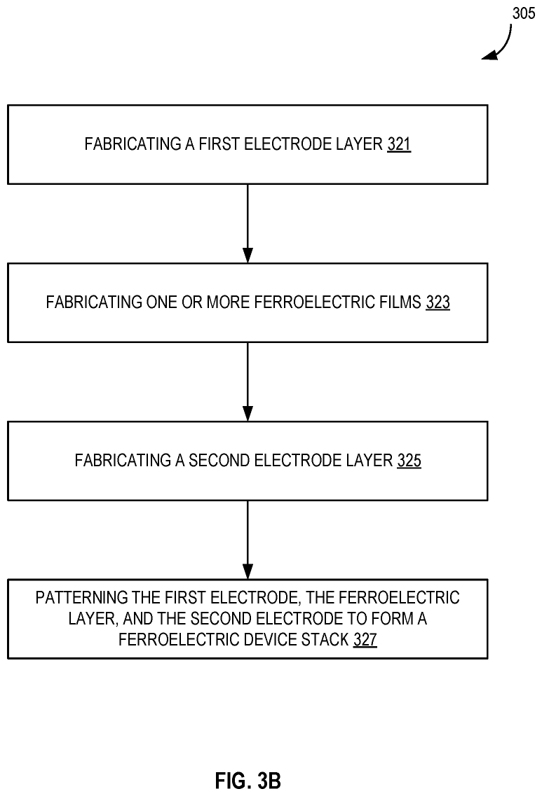

FIG. 3A is a flow chart illustrating an example process 300 for fabricating a ferroelectric device in accordance with some embodiments of the present disclosure. Process 300 may be performed to fabricate a ferroelectric device 100 as described in connection with FIG. 1.

At block 310, a substrate with a first connection pad is provided. The substrate may be the substrate 110 of FIG. 1. The first connection pad may be the first connection pad 120 of FIG. 1.

At block 320, a ferroelectric device stack may be fabricated on the first connection pad and the substrate. The ferroelectric device stack may include a first electrode, a second electrode, and a ferroelectric layer between the first electrode and the second electrode. The ferroelectric device stack may be the ferroelectric device stack 130 of FIG. 1. The ferroelectric device stack may be fabricated by performing operations as described in connection with FIGS. 2A-2E and 3B.

At block 330, deuterium treatment may be performed on the ferroelectric device stacks to obtain deuterium-treated ferroelectric device stacks. For example, the ferroelectric devices stacks may be exposed to a deuterium-containing atmosphere (e.g., an ambient atmosphere with a nitrogen (N₂) to deuterium (D₂) ratio of 96:4) at elevated temperatures (e.g., 350° C.-500° C.), enabling deuterium to reduce electronic defects in the ferroelectric layers of the ferroelectric device stacks. In some embodiments, the deuterium treatment may last between about 15 minutes to about 60 minutes. The deuterium-treated ferroelectric layers and ferroelectric device stacks may thus contain deuterium, which can be detected by measurements such as high-resolution mass spectrometry, etc.

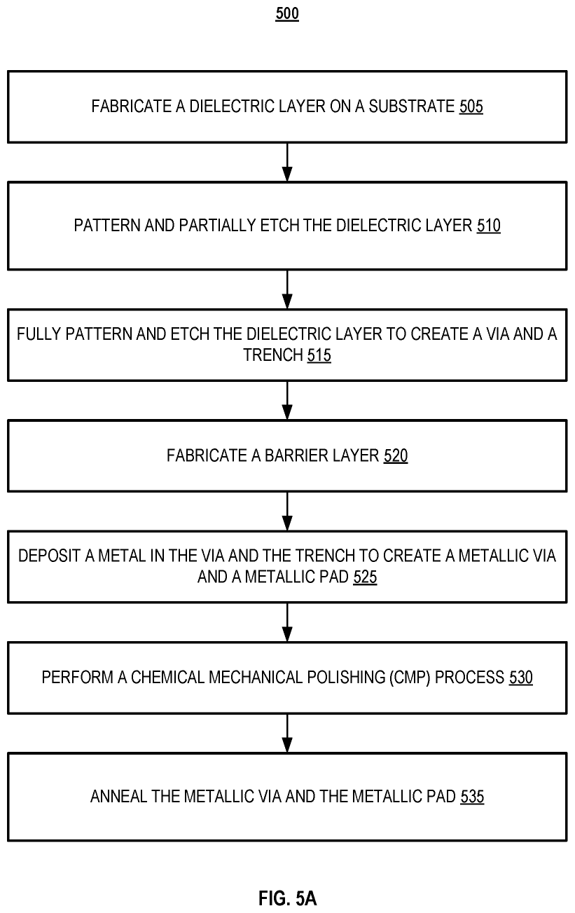

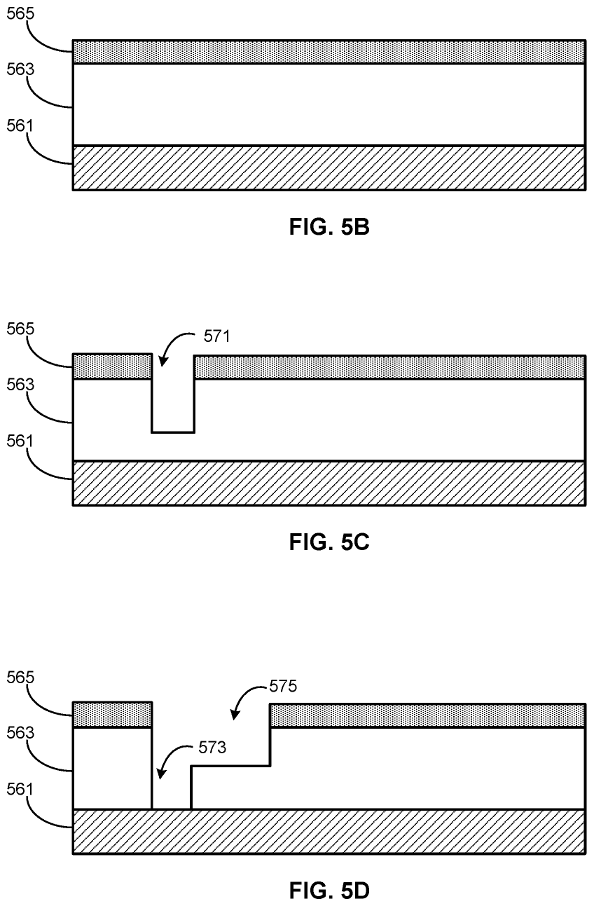

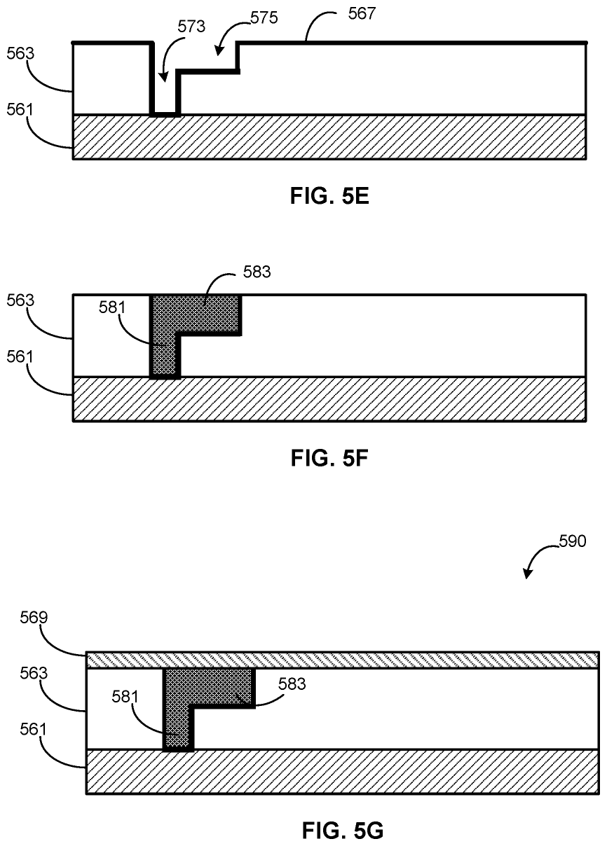

At block 340, a second connection pad may be fabricated on each of the deuterium-treated ferroelectric device stacks. The second connection pad may include one or more metallic vias and/or metallic pads that include conductive materials. The second connection pad may be and/or include the second connection pad 140 of FIG. 1. In some embodiments, the second connection pad may include an interconnect structure fabricated utilizing a dual-damascene fabrication process as described in connection with FIGS. 5A-5G below.

At block 350, heat treatment, including controlled heating and cooling, may be applied to the ferroelectric device stack to achieve the desired ferroelectric o-HfO₂ phase. For example, the heat treatment may involve heating and then cooling the first electrode, the ferroelectric layer, and/or the second electrode at controlled rates. More particularly, for example, the memory device may be heated for crystallization of the t-HfO₂ phase and may then be quickly cooled down to form the ferroelectric o-HfO₂ phase. As a more particular example, amorphous H₂O may be transformed into the t-phase in a heating process and then transformed into the o-phase in a subsequent cooling process. This process can be accomplished by performing rapid thermal annealing (RTA) at a temperature between 350° C. and 500° C. for a duration of 15-60 seconds. Following the heating process, the memory device may be rapidly cooled.

It should be noted that the heat treatment described at block 350 is to be performed after the ferroelectric device has been subjected to its entire thermal budget, which represents the total thermal exposure during the fabrication process. This precaution ensures the stability of the ferroelectric oIII-phase achieved, preventing any further thermal procedures from altering the ferroelectric phase into non-ferroelectric configurations.

FIG. 3B is a flow chart illustrating an example process 305 for fabricating a ferroelectric device stack in accordance with some embodiments of the present disclosure.

At block 321, a first electrode layer may be fabricated on the substrate and the first connection pad. The first electrode layer may be fabricated by depositing a layer of an electrically conductive material over the entire surface of the substrate and the first connection pad. The electrically conductive material may be deposited utilizing atomic layer deposition (ALD), chemical vapor deposition (CVD), metal-organic chemical vapor deposition (MOCVD), physical vapor deposition (PVD), molecular beam epitaxy (MBE) deposition, etc. The electrically conductive material may include, for example, W, Mo, Ru, TiN, TaN, WN, Pt, Pd, Ir, etc. The first electrode layer may be, for example, the first electrode layer 231 as described in connection with FIG. 2B above.

At block 323, one or more ferroelectric films may be fabricated on the first electrode layer. Each of the ferroelectric films may include at least one ferroelectric material (e.g., HfO₂, ZrO₂, HZO(Hf_{0.5}Zr_{0.5}O₂), H₁₋ₓZₓO(Hf₁₋ₓZrₓO₂) with x ranging from 0 to 1, etc.). The ferroelectric films may be fabricated using ALD or other suitable deposition techniques.

In some embodiments, a multilayer structure of multiple ferroelectric films and interface layers alternately stacked on each other may be fabricated. For example, a thin film of a ferroelectric material (e.g., HfO₂ or H₂O) may be deposited on the first electrode and a thin layer of aluminum oxide (e.g., Al₂O₃) may be deposited on top of the ferroelectric film. This fabrication process may be repeated a suitable number of times to create a layered structure of a desirable thickness. In some embodiments, a top ferroelectric layer (e.g., a layer of HfO, a layer of HZO, etc.) may be fabricated on the multilayer structure. In some embodiments, the ferroelectric layer may be fabricated utilizing the techniques described in U.S. patent application Ser. No. 18/539,202, which is incorporated herein by reference in its entirety.

At block 325, a second electrode layer may be fabricated on the ferroelectric films. For example, a layer of a suitable conductive material (e.g., W, Ru, Mo, Pt, Pd, Ir, TiN, TaN, WN, etc.) may be deposited utilizing suitable deposition techniques, such as ALD, CVD, MOCVD, PVD, MBE, etc. In some embodiments, the first electrode layer, the ferroelectric films, and the second electrode layer may be fabricated in the same processing chamber (e.g., an ALD or PVD chamber).

At block 327, one or more portions of the first electrode layer, the ferroelectric films, and the second electrode layer may be selectively removed to form one or more ferroelectric device stacks. For example, the first electrode layer, the ferroelectric films, and the second electrode layer may be patterned to define the geometries of the ferroelectric device stack(s) (e.g., one or more ferroelectric device stacks 130 of FIG. 1). The first electrode layer, the ferroelectric films, and the second electrode layer may be etched (e.g., using suitable etching methods, such as RIE (reactive ion etch), plasma etch, sputter etch, etc.).

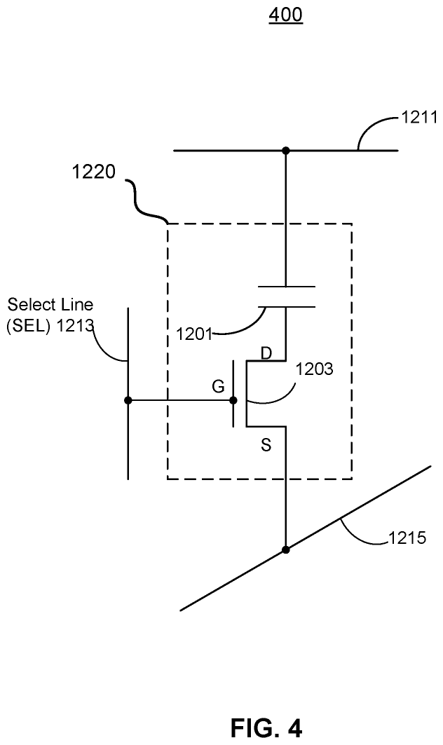

FIG. 4 is a schematic diagram 400 illustrating an example memory cell 1220 in accordance with some embodiments of the present disclosure. Memory cell 1220 may also be referred to as one-transistor-one-capacitor (1T1C) FeRAM configuration.

As shown, memory cell 1220 may include a capacitor 1201 and a transistor 1203 that are connected in series. A transistor may include three terminals that may be marked as gate (G), source(S), and drain (D), respectively. The transistor bulk (B) as a reference terminal is not shown in FIG. 4. Capacitor 1201 may include a ferroelectric device stack as described herein. In some embodiments, transistor 1203 may also be or include a ferroelectric device stack as described herein.

A first terminal of capacitor 1201 may be connected to the drain of transistor 1203. A second terminal of capacitor 1201 may be connected to a line 1211. The source of the transistor 1203 may be connected to a line 1215. The gate of transistor 1203 may be connected to a select line 1213. In one implementation, line 1211 and line 1215 may be a word line and a bit line, respectively. In another implementation, line 1211 and line 1215 may be a bit line and a word line, respectively.

Transistor 1203 may function as a selector and provide control access to capacitor 1201. The gate voltage on transistor 1203 may correspond to a control signal applied to select line 1213 and may enable or disable access to capacitor 1201. When a suitable programming voltage is applied to lines 1215 and/or 1211, the ferroelectric materials in capacitor 1201 may polarize, representing a binary “1” or “0” depending on the polarization direction. This state remains stable even after removing the electric field, allowing for non-volatile data storage. A suitable control signal may be applied to select line 1213 to enable the writing or reading of the polarization state and access to the stored binary data capacitor 1201.

FIG. 5A is a flow chart illustrating an example process 500 for fabricating an interconnect structure including a metallic via and a metallic pad in one process. FIGS. 5B-5G illustrate cross-sectional views of structures for fabricating an interconnect structure 590 as shown in FIG. 5G by implementing process 500 in accordance with some embodiments of the present disclosure.

As shown, process 500 may start at 505 by fabricating a dielectric layer on a substrate. The substrate may be and/or include one or more transistors, interconnect layers, etc. In some embodiments, the substrate may include ferroelectric devices, such as a device including the ferroelectric device stack 130 shown in FIG. 2E. Depositing the dielectric layer may involve depositing one or more interlayer dielectrics (ILDs), such as SiO₂, Si₃N₄, Al₂O₃, etc. For example, as shown in FIG. 5B, a dielectric layer 563 may be fabricated on a substrate 561. In some embodiments, an etch resist 565 may be fabricated on the dielectric layer 563.

At 510, the dielectric layer may be patterned and partially etched. That is, the dielectric layer is partially etched in depth. For example, as shown in FIG. 5C, a via 571 may be fabricated by partially etching the dielectric layer 563 through the patterned etch resist 565.

At 515, the partially etched dielectric layer may be fully etched to create a via and/or a trench. The dielectric is fully etched in depth while maintaining an etching profile for via and trench due to the conformal etching. For example, as shown in FIG. 5D, a via 573 and a trench 575 may be created by etching the partially etched dielectric layer 563 through the re-patterned etch resist 565.

At 520, a barrier layer may be fabricated. For example, as shown in FIG. 5E, a barrier layer 567 (e.g., a layer including Ta or TaN) may be deposited on the fully etched dielectric layer and over the sidewalls of the via 573 and the trench 575.

At 525, a metal may be deposited to create a metallic via and a metallic pad. For example, a thin Cu seed layer may be deposited by physical vapor deposition (PVD) followed by the electroplating of Cu, which fills the via and the trench. The metal deposition may also create one or more metal wires. A metal layer may be deposited (e.g., by plating) in the via 573 and the trench 575 to create a metallic via 581 and a metallic pad 583, respectively.

At 530, a chemical mechanical polishing (CMP) process is performed. For example, the metallic via 581, the metallic pad 583, and metal wires (not shown) may be patterned and processed in the CMP process to remove excess Cu and planarize the surface, as shown in FIG. 5F. In some embodiments, as shown in FIG. 5G, a capping layer 569 (e.g., a Ta, TaN, or SiN layer) may be deposited.

At 535, the metallic via and the metallic pad may be annealed. For example, the interconnect structure 590 of FIG. 5G may be annealed at the annealing temperatures (e.g., 350-450° C.) in a forming gas flow (e.g., a mixture of N₂ and H₂) for a suitable period of time (e.g., 15-30 minutes).

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” may be used to mean within +20% of a target dimension in some embodiments, within +10% of a target dimension in some embodiments, within +5% of a target dimension in some embodiments, and yet within +2% in some embodiments. The terms “approximately” and “about” may include the target dimension.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. An apparatus, comprising:
a first electrode;
a ferroelectric layer fabricated on the first electrode, wherein the ferroelectric layer comprises a ferroelectric material and deuterium; and
a second electrode fabricated on the ferroelectric layer.

2. The apparatus of claim 1, wherein the ferroelectric material comprises a deuterium-treated metal oxide, and wherein the metal oxide comprises at least one of hafnium oxide (HfO₂), zirconium oxide (ZrO₂), zirconium-doped hafnium oxide (Hf₁₋ₓZrₓO₂ with x ranging from 0 to 1), scandium-doped aluminum nitride (Al₁₋ₓScₓN with x>0.3), titanates (BaTiO₃), niobates (LiNbO₃), or tantalates (NaTaO₃).

3. The apparatus of claim 1, wherein the ferroelectric material is interstitially doped with at least one interstitial dopant, and wherein the at least one interstitial dopant comprises at least one of H, N, C, B, or F.

4. The apparatus of claim 1, wherein the first electrode comprises at least one of tungsten, ruthenium, molybdenum, titanium nitride, tantalum nitride, tungsten nitride, platinum, palladium, or iridium.

5. The apparatus of claim 1, wherein the second electrode comprises at least one of tungsten, ruthenium, molybdenum, titanium nitride, tantalum nitride, tungsten nitride, platinum, palladium, or iridium.

6. The apparatus of claim 1, further comprising a first connection pad, wherein the first electrode is fabricated on the first connection pad, and wherein the first connection pad comprises a conductive material.

7. The apparatus of claim 6, further comprising a substrate, wherein the first connection pad is fabricated on the substrate.

8. The apparatus of claim 7, further comprising a second connection pad, wherein the second connection pad is fabricated on the second electrode.

9. The apparatus of claim 8, wherein the second connection pad comprises a metallic pad and a metallic via.

10. A method, comprising:
fabricating a ferroelectric device stack, wherein the ferroelectric device stack comprises a first electrode, a second electrode, and a ferroelectric layer between the first electrode and the second electrode, wherein the ferroelectric layer comprises a ferroelectric material; and
performing deuterium treatment on the ferroelectric device stack to obtain a deuterium-treated ferroelectric device stack, wherein the ferroelectric layer in the deuterium-treated ferroelectric device stack comprises deuterium.

11. The method of claim 10, further comprising fabricating a connection pad on the deuterium-treated ferroelectric device stack.

12. The method of claim 11, wherein fabricating the connection pad comprises fabricating at least one of a metallic pad or a metallic via.

13. The method of claim 10, wherein the ferroelectric material comprises a metal oxide, and wherein the metal oxide comprises at least one of hafnium oxide (HfO₂), zirconium oxide (ZrO₂), zirconium-doped hafnium oxide (Hf₁₋ₓZrₓO₂ with x ranging from 0 to 1), scandium-doped aluminum nitride (Al₁₋ₓScₓN with x>0.3), titanates (BaTiO₃), niobates (LiNbO₃), or tantalates (NaTaO₃).

14. The method of claim 13, wherein the first electrode comprises at least one of tungsten, ruthenium, molybdenum, titanium nitride, tantalum nitride, tungsten nitride, platinum, palladium, or iridium.

15. The method of claim 14, wherein the second electrode comprises at least one of tungsten, ruthenium, molybdenum, titanium nitride, tantalum nitride, tungsten nitride, platinum, palladium, or iridium.

16. The method of claim 10, wherein performing the deuterium treatment on the ferroelectric device stack comprises exposing the ferroelectric device stack in an ambient atmosphere comprising nitrogen gas (N₂) and deuterium gas (D₂).

17. The method of claim 16, wherein fabricating the ferroelectric device stack comprises:
fabricating, on a connection pad, a first electrode layer;
fabricating one or more ferroelectric films on the first electrode layer; and
fabricating a second electrode layer on the ferroelectric films.

18. The method of claim 17, wherein fabricating the ferroelectric device stack further comprises selectively removing one or more portions of the first electrode layer, the ferroelectric films, and the second electrode layer.

19. The method of claim 10, wherein the ferroelectric device stack is fabricated on a connection pad, wherein the connection pad comprises a conductive material.

20. The method of claim 10, further comprising applying heat treatment to the deuterium-treated ferroelectric device stack.
